(19) United States
(12) Patent Application Publication
(10) Pub. No.: US 2025/0089497 A1
(43) Pub. Date: Mar. 13, 2025

(54) DISPLAY DEVICE AND WEARABLE DEVICE

(71) Applicant: Samsung Display Co., LTD., Yongin-si (KR)

(72) Inventors: Chul Min BAE, Yongin-si (KR); Ji Hye HAN, Yongin-si (KR)

(21) Appl. No.: 18/741,547

(22) Filed: Jun. 12, 2024

(30) Foreign Application Priority Data
Sep. 11, 2023 (KR) 10-2023-0120657

(51) Int. Cl. H10K 59/131; G02B 27/01; H10K 59/121; H10K 59/122

(52) U.S. Cl. CPC H10K 59/131; G02B 27/0172; H10K 59/1213; H10K 59/1216; H10K 59/122

(57) ABSTRACT

One or more embodiments of the present disclosure provide a display device including a substrate having a display area and a non-display area, sub-pixels in the display area, a metal line crossing the non-display area and the display area, and extending in the display area to be spaced apart from light-emitting areas of the sub-pixels in a plan view, and an auxiliary circuit connected to the metal line in the display area.

### CROSS-REFERENCE TO RELATED APPLICATION

The present application claims priority to, and the benefit of, Korean Patent Application No. 10-2023-0120657, filed on Sep. 11, 2023, in the Korean Intellectual Property Office, the entire disclosure of which is incorporated herein by reference.

### BACKGROUND

### 1. Field

The present disclosure relates to a display device and a wearable device.

### 2. Description of the Related Art

As information technology has developed, importance of a display device, which is a connection medium between a user and information, has been highlighted. Accordingly, the use of display devices, such as a liquid crystal display device, an organic light-emitting display device, and the like has been increasing.

The display device displays an image using pixels. To implement augmented reality (AR), virtual reality (VR), and mixed reality (MR), the display device may suitably have more pixels located on a small display surface.

As the gap between pixels narrows, a leakage current through a common layer of adjacent pixels may become a problem.

### SUMMARY

The present disclosure provides a display device and a wearable device that may a reduce or prevent leakage current through a common layer between adjacent pixels.

One or more embodiments of the present disclosure provide a display device including a substrate having a display area and a non-display area, sub-pixels in the display area, a metal line crossing the non-display area and the display area, and extending in the display area to be spaced apart from light-emitting areas of the sub-pixels in a plan view, and an auxiliary circuit connected to the metal line in the display area.

The sub-pixels and the auxiliary circuit may be coupled to a first power voltage node.

The auxiliary circuit may include an auxiliary transistor coupled between the metal line and the first power voltage node.

A first electrode and a gate electrode of the auxiliary transistor may be coupled to the first power voltage node.

A second electrode of the auxiliary transistor may be coupled to the metal line, and may be configured to receive a reference voltage.

The sub-pixels may include a light-emitting element, a first transistor having a gate electrode coupled to a first node, a first electrode coupled to a second node, and a second electrode coupled to an anode of the light-emitting element, a second transistor having a gate electrode coupled to a gate line, a first electrode coupled to a data line, and a second electrode coupled to the first node, and a storage capacitor having a first electrode coupled to the first power voltage node, and a second electrode coupled to the first node.

The sub-pixels may further include a third transistor having a gate electrode coupled to the second node, a first electrode coupled to the first power voltage node, and a second electrode coupled to the second node, and a fourth transistor having a gate electrode and a first electrode coupled to the anode of the light-emitting element, and a second electrode configured to receive a reference voltage.

One or more other embodiments of the present disclosure provide a display device including a substrate containing a display area and a non-display area, sub-pixels in the display area, metal lines crossing the non-display area and the display area, and extending in the display area to be spaced apart from light-emitting areas of the sub-pixels in a plan view, and auxiliary circuits coupled to at least one of the metal lines in the display area.

A number of the auxiliary circuits may be less than a number of the sub-pixels.

The metal lines may extend in a first direction, wherein, in the display area, a density of the auxiliary circuits increases toward the first direction.

At least one of the auxiliary circuits may be coupled to two or more points of a same metal line.

At least one of the auxiliary circuits may be coupled to two or more different metal lines.

The auxiliary circuits may include a first auxiliary circuit and a second auxiliary circuit coupled to a same metal line, wherein a length of a first connection line coupling the first auxiliary circuit and one of the metal lines is longer than a length of a second connection line coupling the second auxiliary circuit and the one of the metal lines.

The display device may further include a first metal pad in the non-display area, and coupled to first ends of the metal lines, and a second metal pad in the non-display area, and coupled to second ends of the metal lines, wherein the display area is between the first metal pad and the second metal pad.

The metal lines may be on a pixel-defining layer defining the light-emitting areas of the sub-pixels in the display area.

The metal lines may respectively contact cathodes of light-emitting elements of the sub-pixels.

Light-emitting elements of the sub-pixels may include a first light-emitting portion, and a second light-emitting portion stacked on the first light-emitting portion, and contacting a corresponding one of the metal lines.

One or more other embodiments of the present disclosure provide a wearable device including a first display panel, and a second display panel, wherein the first display panel and the second display panel include a substrate including a display area and a non-display area, sub-pixels in the display area, metal lines crossing the non-display area and the display area, and extending in the display area to be spaced apart from light-emitting areas of the sub-pixels in a plan view, and auxiliary circuits coupled to at least one of the metal lines in the display area.

The sub-pixels and the auxiliary circuits may be coupled to a first power voltage node.

The auxiliary circuits may include an auxiliary transistor coupled between one of the metal lines and the first power voltage node, wherein a first electrode and a gate electrode of the auxiliary transistor are coupled to the first power voltage node, and wherein a second electrode of the auxiliary transistor is coupled to the one of the metal lines.

According to the display device and the wearable device of the present disclosure, it is possible to reduce or prevent a leakage current through a common layer between adjacent pixels.

### BRIEF DESCRIPTION OF DRAWINGS

FIG. 1 illustrates a block diagram of one or more embodiments of a display device.

FIG. 2 illustrates a top plan view of one or more embodiments of a display panel of FIG. 1.

FIG. 3 illustrates a block diagram of a sub-pixel and an auxiliary circuit.

FIG. 4 is a drawing for explaining one or more embodiments of a sub-pixel and an auxiliary circuit.

FIG. 5 is a drawing for explaining one or more other embodiments of a sub-pixel and an auxiliary circuit.

FIG. 6 illustrates an exploded perspective view of a portion of the display panel of FIG. 2.

FIG. 7 illustrates a top plan view of a relationship between sub-pixels and metal lines.

FIG. 8 illustrates a cross-sectional view of one or more embodiments of a light-emitting structure.

FIG. 9 illustrates a cross-sectional view of one or more other embodiments of a light-emitting structure.

FIG. 10 illustrates a cross-sectional view taken along the line I-I′ of FIG. 7.

FIG. 11 illustrates a cross-sectional view of one or more other embodiments of FIG. 10.

FIG. 12A to FIG. 12F are drawings for explaining other embodiments of the display panel of FIG. 2.

FIG. 13 illustrates a block diagram of one or more embodiments of a display system.

FIG. 14 illustrates a perspective view of an example of application of the display system of FIG. 13.

FIG. 15 illustrates a head-mounted display device worn on a user of FIG. 14.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In addition, the expression “equal to or the same as” in the description may mean “substantially equal to or the same as”. That is, it may be the same enough to convince those skilled in the art to be the same. Even other expressions may be expressions from which “substantially” is omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

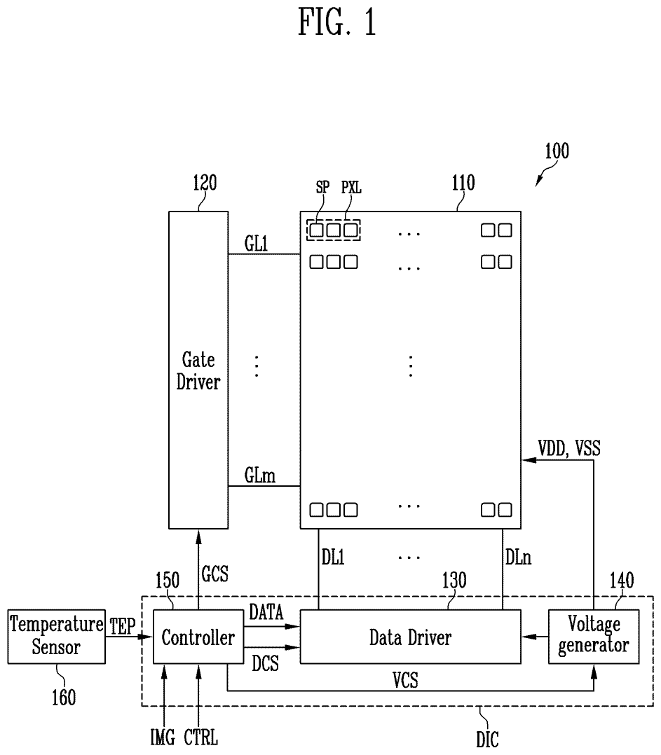

FIG. 1 illustrates a block diagram of one or more embodiments of a display device.

Referring to FIG. 1, a display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, the sub-pixels SP may respectively generate light of a corresponding color, such as red, green, blue, cyan, magenta, yellow, or the like. Two or more of the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting gate signals in synchronization with the timing at which data signals are applied, and the like.

The gate driver 120 may be located on one side of the display panel 110. However, embodiments are not limited thereto. For example, the gate driver 120 may be divided into two or more physically and/or logically separated drivers, and the drivers may be respectively located on one side of the display panel 110 and on the other side of the display panel 110 opposite to the one side. As described above, the gate driver 120 may be located around the display panel 110 in various forms according to the embodiments.

The data driver 130 is connected to the sub-pixels SP arranged in a column direction through the first to n-th data lines DL1 to DLn. The data driver 130 receives image data DATA and data control signal DCS from the controller 150. The data driver 130 operates in response to the data control signal DCS. In embodiments, the data control signal DCS may include a source start pulse, a source shift clock, a source output enable signal, and the like.

The data driver 130 may use voltages from the voltage generator 140 to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to constituent elements of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level that is lower than the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation to sense electrical characteristics of transistors and/or light-emitting elements of the sub-pixels SP, a reference voltage (e.g., predetermined reference voltage) may be applied to the first to n-th data lines DL1 to DLn, and the voltage generator 140 may generate the reference voltage.

The controller 150 controls various operations of the display device 100. The controller 150 receives input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In embodiments, the controller 150 may output the image data DATA by aligning the input image data IMG to be suitable for the disposition of the sub-pixels SP.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, or the controller 150 may be provided as a component separated from the driver integrated circuit DIC.

In some embodiments, the display device 100 may include at least one temperature sensor 160. The temperature sensor 160 is configured to sense a surrounding temperature, and to generate temperature data TEP representing the sensed temperature. In embodiments, the temperature sensor 160 may be adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control the data signals and the first and second power voltages VDD and VSS by controlling components, such as the data driver 130 and/or the voltage generator 140.

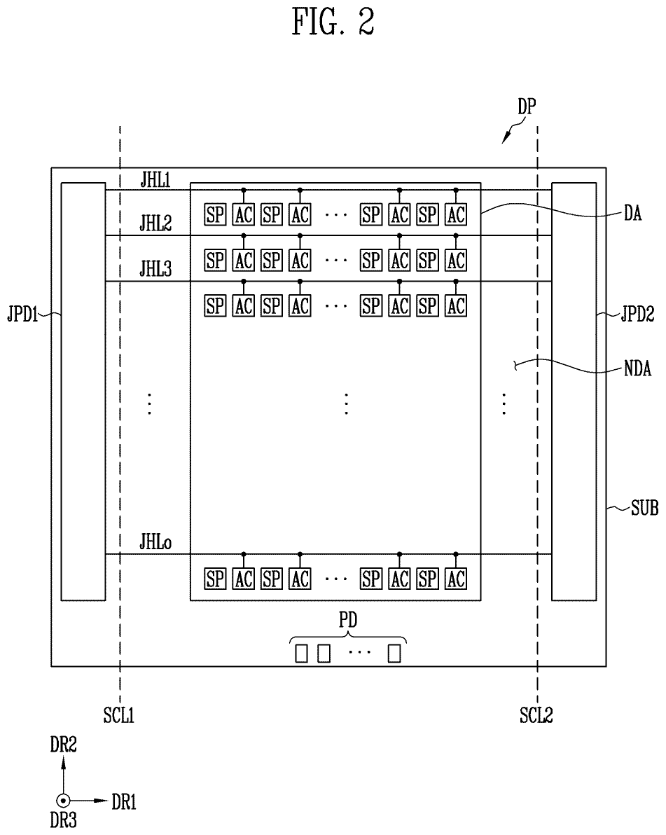

FIG. 2 illustrates a top plan view of one or more embodiments of a display panel of FIG. 1.

Referring to FIG. 2, one or more embodiments DP of the display panel 110 of FIG. 1 may include a display area DA and a non-display area NDA. The display panel DP displays an image through the display area DA. The non-display area NDA is located around the display area DA.

The display panel DP may include a substrate SUB, sub-pixels SP, auxiliary circuits AC, a first metal pad JPD1, a second metal pad JPD2, metal lines JHL1 to JHLo, and pads PD.

When the display panel DP is used as a display screen for a head-mounted display (HMD), a virtual reality (VR) device, a mixed reality (MR) device, or an augmented reality (AR) device, the display panel DP may be positioned very close to the user's eyes. In this case, the sub-pixels SP with relatively high integration are suitable. To increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDoS) display device.

The sub-pixels SP are located in the display area DA on the substrate SUB. The sub-pixels SP may be arranged in a matrix format along a first direction DR1 and a second direction DR2 that intersects the first direction DR1. However, embodiments are not limited thereto. For example, the sub-pixels SP may be arranged in a zigzag form along first direction DR1 and second direction DR2. For example, the sub-pixels SP may be located in a PENTILE™ shape (e.g., a RGBG matrix structure, PENTILE™ being a registered trademark of Samsung Display Co., Ltd., Republic of Korea). The first direction DR1 may be a row direction, and the second direction DR2 may be a column direction. Two or more of the plurality of sub-pixels SP may configure one pixel PXL.

The substrate SUB may include the display area DA and the non-display area NDA. A constituent element to control the sub-pixels SP may be located in the non-display area NDA on the substrate SUB. For example, wires connected to the sub-pixels SP, such as the first to m-th gate lines GL1 to GLm and the first to n-th data lines DL1 to DLn of FIG. 1, may be space-efficiently located in the non-display area NDA.

The first metal pad JPD1 may be located in the non-display area NDA. The first metal pad JPD1 may have a substantially rectangular shape with a long side extending in the second direction DR2, and a short side extending in the first direction DR1. A length of the long side may be similar to a length of the display area DA in the second direction DR2. The first metal pad JPD1 may include at least one or more metallic materials. For example, the first metal pad JPD1 may include a material with high resistivity and melting point, such as molybdenum (Mo), titanium (Ti), or a titanium nitride (TiN). The first metal pad JPD1 may be located in a direction opposite to the first direction DR1 from the display area DA.

The second metal pad JPD2 may be located in the non-display area NDA, and may be spaced from the first metal pad JPD1 in the first direction DR1. The second metal pad JPD2 may have a substantially rectangular shape with a long side extending in the second direction DR2, and a short side extending in the first direction DR1. A length of the long side may be similar to a length of the display area DA in the second direction DR2. The second metal pad JPD2 may include at least one or more metallic materials. For example, the second metal pad JPD2 may include a material with high resistivity and melting point, such as molybdenum (Mo), titanium (Ti), or a titanium nitride (TiN). The second metal pad JPD2 may be located in the first direction DR1 from the display area DA. That is, the display area DA may be located between the first metal pad JPD1 and the second metal pad JPD2.

The metal lines JHL1 to JHLo (o may be an integer greater than 1) may cross the non-display area NDA and the display area DA, and may extend in the display area DA so as not to overlap the light-emitting areas of the sub-pixels SP. That is, the metal lines JHL1 to JHLo may extend to be spaced apart from the light-emitting areas of the sub-pixels SP on a plane in the display area DA. The metal lines JHL1 to JHLo may connect the first metal pad JPD1 and the second metal pad JPD2. The metal lines JHL1 to JHLo may be parallel to each other in the second direction DR2. One end of each of the metal lines JHL1 to JHLo may be connected to the first metal pad JPD1, and the other ends of the metal lines JHL1 to JHLo may be connected to the second metal pad JPD2. For example, the metal lines JHL1 to JHLo may include a material with high resistivity and melting point, such as molybdenum (Mo), titanium (Ti), or a titanium nitride (TiN).

The first metal pad JPD1, the second metal pad JPD2, and the metal lines JHL1 to JHLo may be integrally formed using the same material and process.

When a power voltage is applied to the first metal pad JPD1, heat generation due to Joule heating may occur in the metal lines JHL1 to JHLo. The power voltage may be a single pulse, or may include a plurality of pulses. Due to the heat generation, an organic material adjacent to the metal lines JHL1 to JHLo may be sublimated. Accordingly, during the operation of the display device 100, a leakage current through organic materials may be reduced or prevented.

However, voltages of the metal lines JHL1 to JHLo near the second metal pad JPD2 may be less than voltages of the metal lines JHL1 to JHLo near the first metal pad JPD1. This is due to a voltage drop phenomenon (IR drop) that occurs while a current flows from the first metal pad JPD1 to the second metal pad JPD2.

To compensate for this voltage drop phenomenon, the display device 100 may include the auxiliary circuits AC. The auxiliary circuits AC may be connected to at least one of the metal lines JHL1 to JHLo in the display area DA. When the power voltage is applied to the first metal pad JPD1, the auxiliary circuits AC may provide an auxiliary current to the connected metal lines JHL1 to JHLo. Accordingly, the voltage drop phenomenon may be compensated.

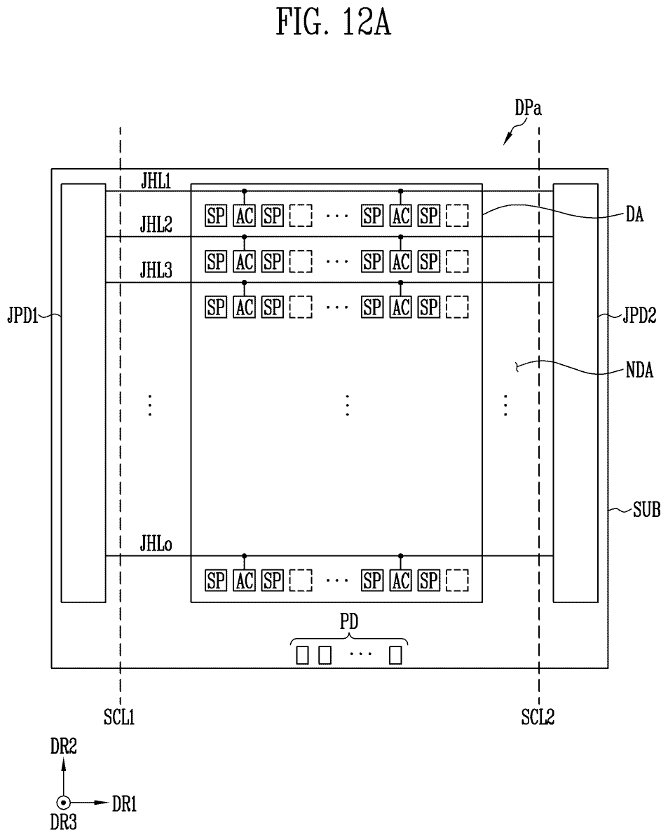

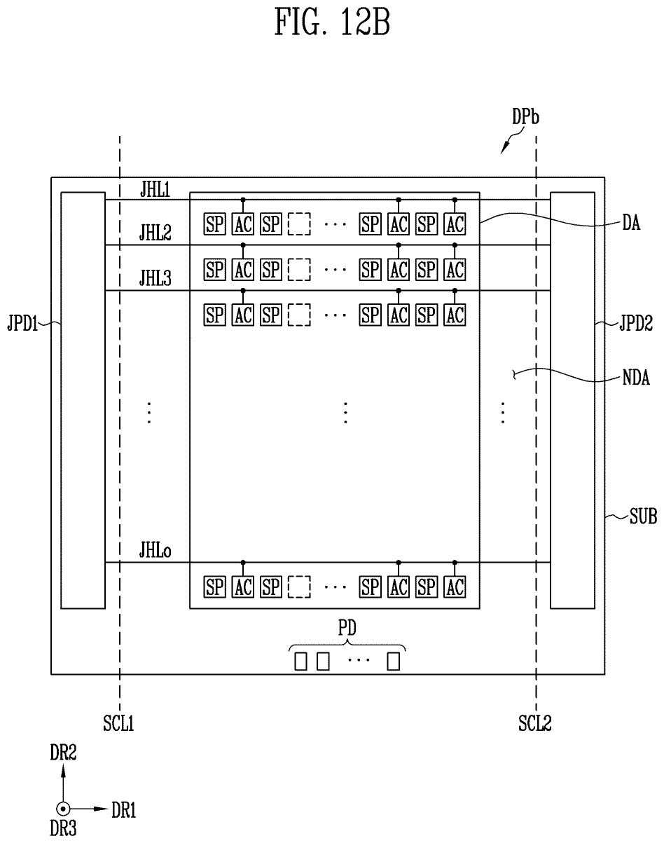

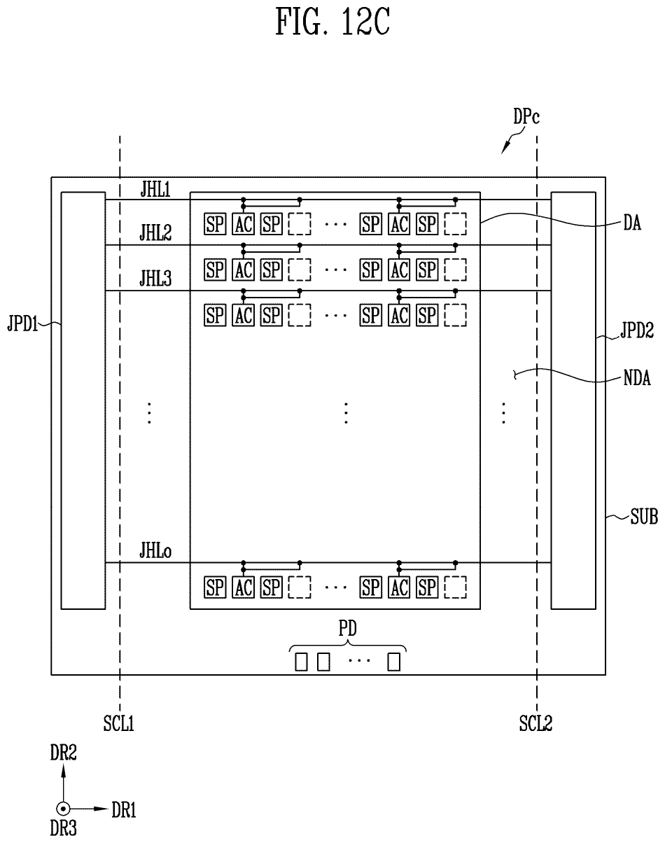

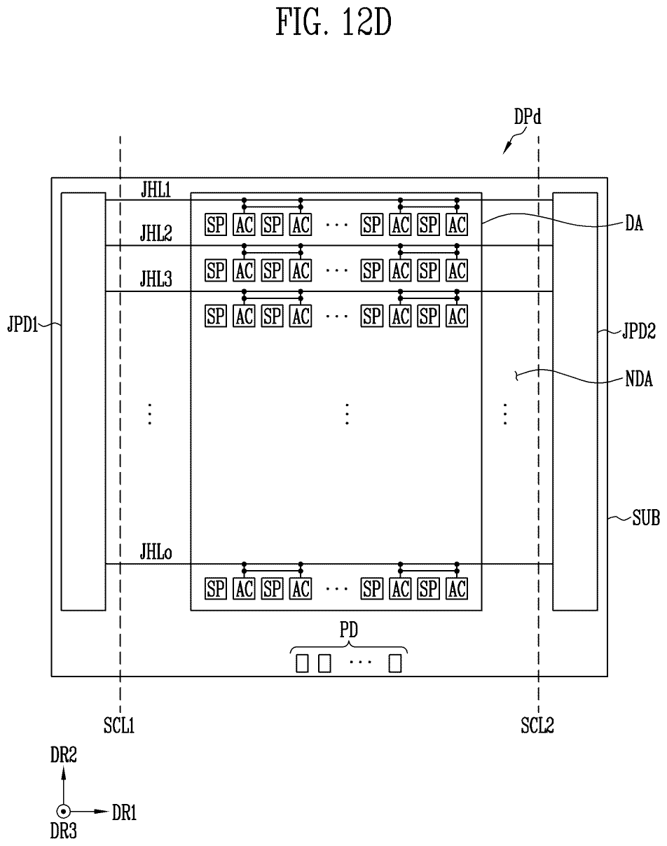

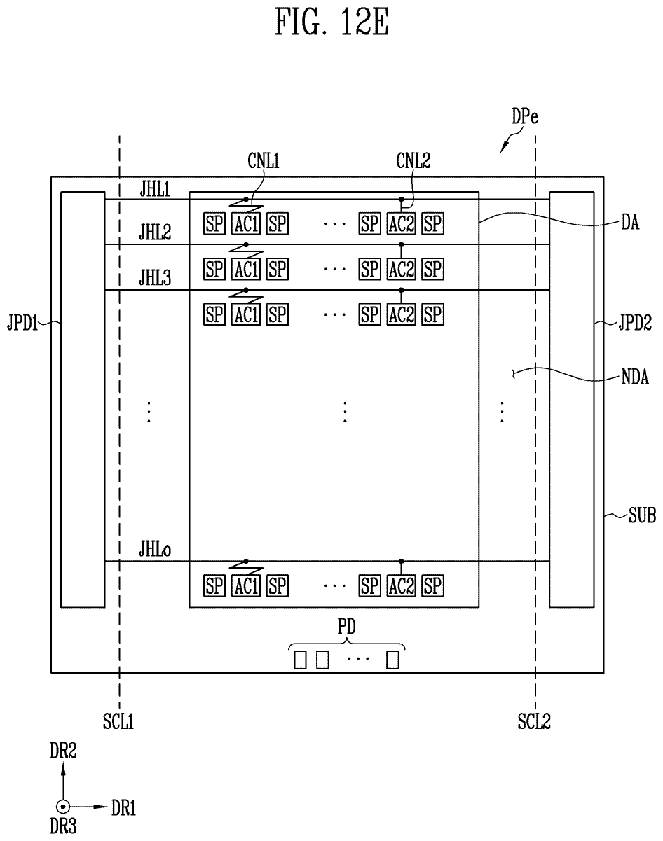

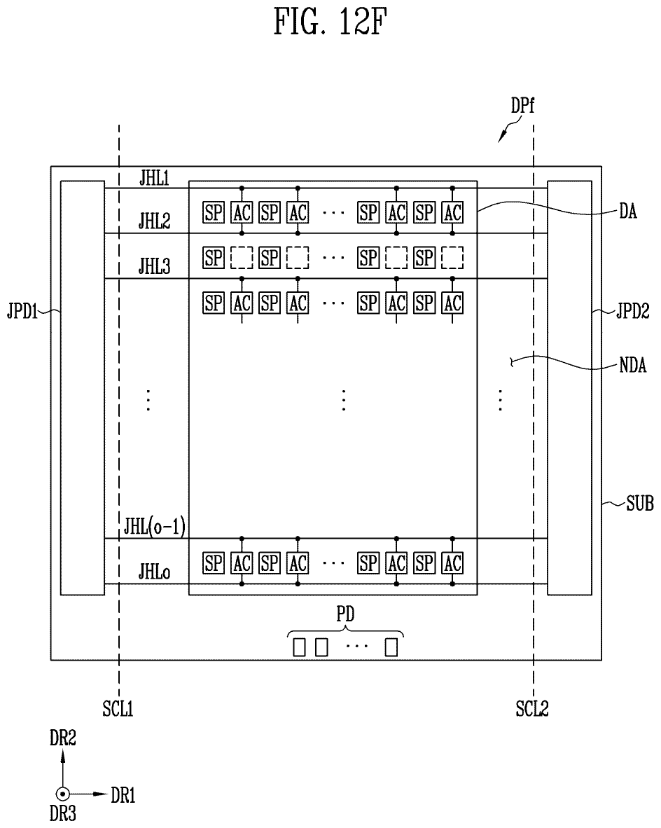

The number, position, and connection relationship of the auxiliary circuits AC may be variously set. In FIG. 2, the number of the auxiliary circuits AC may be equal to the number of the sub-pixels SP. The auxiliary circuits AC in a row unit may be connected to the same metal line. The density of the auxiliary circuits AC may be constant throughout the display area DA. The number, position, and connection relationship of the auxiliary circuits AC will be more variously described later with reference to FIG. 12A to FIG. 12F. In the Joule heating process, the auxiliary circuits AC may be provided with the power voltage through at least some of the pads PD.

A virtual first cutting line SCL1 may extend in the second direction DR2 between the first metal pad JPD1 and the display area DA. The first cutting line SCL1 may cross the metal lines JHL1 to JHLo. A virtual second cutting line SCL2 may extend in the second direction DR2 between the second metal pad JPD2 and the display area DA. The second cutting line SCL2 may cross the metal lines JHL1 to JHLo.

After the Joule heating process, the display panel DP is cut along the cutting lines SCL1 and SCL2, so that the first metal pad JPD1 and the second metal pad JPD2 may not exist in the final product. In one or more other embodiments, by not cutting the display panel DP along the cutting lines SCL1 and SCL2, the first metal pad JPD1 and the second metal pad JPD2 may exist in the final product.

At least one of the gate driver 120, the data driver 130, the voltage generator 140, the controller 150, and the temperature sensor 160 in FIG. 1 may be integrated in the non-display area NDA of the display panel DP. In embodiments, the gate driver 120 of FIG. 1 may be mounted on the display panel DP, and may be located in the non-display area NDA. In other embodiments, the gate driver 120 may be implemented as an integrated circuit separated from the display panel DP. In embodiments, the temperature sensor 160 may be located in the non-display area NDA to detect the temperature of the display panel DP.

The pads PD are located in the non-display area NDA on the substrate SUB. At least some of the pads PD may be electrically connected to the sub-pixels SP through wires. For example, some of the pads PD may be connected to the sub-pixels SP through the first to n-th data lines DL1 to DLn.

The pads PD may interface the display panel DP to other constituent elements of the display device 100 (see FIG. 1). In embodiments, voltages and signals suitable for operations of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments, the circuit board may be electrically connected to the pads PD by using a conductive adhesive member, such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

In embodiments, the display area DA may have various shapes. The display area DA may have a closed-loop shape including sides of a straight line and/or a curved line. For example, the display area DA may have shapes, such as a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials with flexible properties.

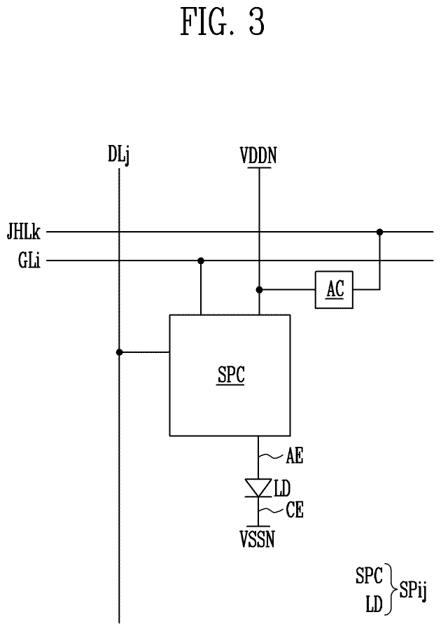

FIG. 3 illustrates a block diagram of a sub-pixel and an auxiliary circuit.

Referring to FIG. 3, among the sub-pixels SP, a sub-pixel SPij located in an i-th row (i is an integer greater than or equal to 1, and less than or equal to m) and a j-th column (j is an integer greater than or equal to 1, and less than or equal to n) is illustrated as an example. The sub-pixel SPij may include a sub-pixel circuit SPC and a light-emitting element LD.

In addition, referring to FIG. 3, the auxiliary circuit AC is illustrated as an example. The auxiliary circuit AC may be connected between at least one metal line JHLk of the metal lines JHL1 to JHLo and a first power voltage node VDDN. The sub-pixel SPij and the auxiliary circuit AC may be commonly connected to the first power voltage node VDDN.

The light-emitting element LD is connected between the first power voltage node VDDN and a second power voltage node VSSN. In this case, the first power voltage node VDDN is a node that transmits the first power voltage VDD of FIG. 1, and the second power voltage node VSSN is a node that transmits the second power voltage VSS of FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi of the first to m-th gate lines GL1 to GLm of FIG. 1 and a j-th data line DLj of the first to n-th data lines DL1 to DLn of FIG. 1. The sub-pixel circuit SPC is configured to control the light-emitting element LD according to signals received through these signal lines.

The sub-pixel circuit SPC may operate in response to a gate signal received through the i-th gate line GLi. The sub-pixel circuit SPC may receive a data signal through the j-th data line DLj. For example, the sub-pixel circuit SPC may respond to the gate signal to store a voltage corresponding to the data signal. Based on the voltage stored in the sub-pixel circuit SPC, the light-emitting element LD may generate light having a luminance corresponding to the data signal.

During the process of Joule heating, the auxiliary circuit AC may supply an auxiliary current to the metal line JHLk based on the auxiliary voltage applied to the first power voltage node VDDN. However, the auxiliary circuit AC may not operate when the display device 100 displays an image. For example, when the display device 100 displays an image, the first power voltage VDD of the first power voltage node VDDN may be blocked by the auxiliary circuit AC. Accordingly, the first power voltage VDD may not be applied to the metal line JHLk.

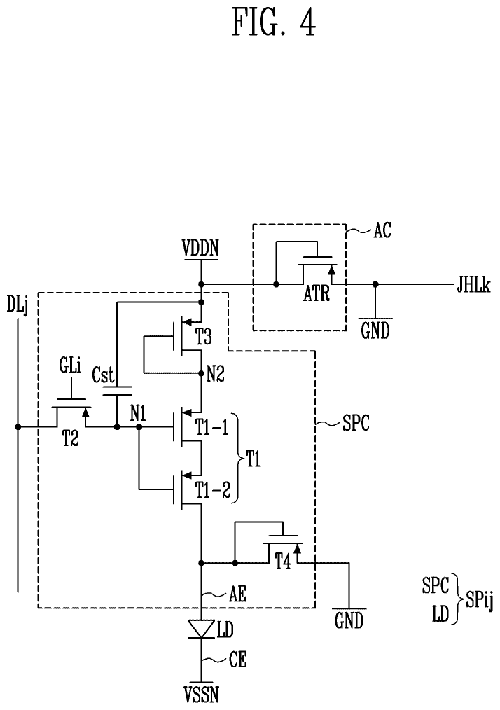

FIG. 4 is a drawing for explaining one or more embodiments of a sub-pixel and an auxiliary circuit.

Referring to FIG. 4, the sub-pixel SPij may include the sub-pixel circuit SPC and the light-emitting element LD. The sub-pixel circuit SPC may include first to fourth transistors T1, T2, T3, and T4 and a storage capacitor Cst.

In the first transistor T1, a gate electrode may be connected to a first node N1, a first electrode may be connected to a second node N2, and a second electrode may be connected to the anode electrode AE of the light-emitting element LD. The first transistor T1 may include sub-transistors T1-1 and T1-2 connected in series. The first transistor T1 may be a driving transistor.

In the second transistor T2, a gate electrode may be connected to the i-th gate line GLi, a first electrode may be connected to the j-th data line DLj, and a second electrode may be connected to the first node N1. The second transistor T2 may be a switching transistor.

In the third transistor T3, a gate electrode may be connected to the second node N2, a first electrode may be connected to the first power voltage node VDDN, and a second electrode may be connected to the second node N2.

In the fourth transistor T4, a gate electrode and a first electrode may be connected to the anode electrode AE of the light-emitting element LD, and a second electrode may receive a reference voltage GND. The reference voltage GND may be set to be less than the first power voltage VDD. The reference voltage GND may be the same as the second power voltage VSS. In one or more other embodiments, the reference voltage GND may be different from the second power voltage VSS.

In the storage capacitor Cst, a first electrode may be connected to the first power voltage node VDDN, and a second electrode may be connected to the first node N1.

The light-emitting element LD may include the anode electrode AE, the cathode electrode CE, and the light-emitting layer. The light-emitting layer may be located between the anode electrode AE and the cathode electrode CE.

When a gate signal at a turn-on level (low level) is applied to the i-th gate line GLi, the second transistor T2 may be turned on. In this case, the data signal applied to the j-th data line DLj may be applied to the first node N1 through the second transistor T2. The storage capacitor Cst may maintain the voltage of the data signal. In response to the voltage of the data signal, the first transistor T1 may determine an amount of a driving current flowing from the first power voltage node VDDN to the second power voltage node VSSN. The light-emitting element LD may emit light with luminance corresponding to the amount of the driving current.

The third transistor T3 and the fourth transistor T4 are diode-connected transistors, which may limit the direction of current so that the current does not flow in the reverse direction. In some embodiments, the third transistor T3 and the fourth transistor T4 may be removed from the sub-pixel circuit SPC. When the third transistor T3 is removed, the second node N2 may be directly connected to the first power voltage node VDDN.

The auxiliary circuit AC may include an auxiliary transistor ATR. The auxiliary transistor ATR may be connected between at least one metal line JHLk of the metal lines JHL1 to JHLo and the first power voltage node VDDN. The auxiliary transistor ATR may be diode-connected. A first electrode and a gate electrode of the auxiliary transistor ATR may be connected to the first power voltage node VDDN. A second electrode of the auxiliary transistor ATR may be connected to at least one metal line JHLk of the metal lines JHL1 to JHLo. The second electrode of the auxiliary transistor ATR may receive the reference voltage GND. The reference voltage GND may be the same as the second power voltage VSS. In one or more other embodiments, the reference voltage GND may be different from the second power voltage VSS. Additionally, the reference voltage GND applied to the second electrode of the auxiliary transistor ATR may be the same as or different from the reference voltage GND applied to the second electrode of the fourth transistor T4.

During the Joule heating process, the auxiliary voltage applied to the first power voltage node VDDN may be greater than the voltage of the metal lines JHL1 to JHLo. For example, the difference between the auxiliary voltage and the voltage applied to the metal lines JHL1 to JHLo may be greater than the breakdown voltage of the auxiliary transistor ATR. Accordingly, an auxiliary current may flow from the first power voltage node VDDN toward the metal lines JHL1 to JHLo, and the auxiliary current may compensate for the voltage drop of the metal lines JHL1 to JHLo.

Meanwhile, when the display device 100 displays an image, the difference between the first power voltage VDD of the first power voltage node VDDN and the reference voltage GND may be less than the breakdown voltage of the auxiliary transistor ATR. Accordingly, the likelihood of a current in the reverse direction may be reduced or prevented from flowing from the first power voltage node VDDN toward the metal lines JHL1 to JHLo.

The first to fourth transistors T1, T2, T3, and T4 and the auxiliary transistor ATR may be P-type transistors. Each of the transistors T1, T2, T3, T4, and ATR may be a metal oxide silicon field effect transistor (MOSFET). However, embodiments are not limited thereto. For example, at least one of the transistors T1, T2, T3, T4, or ATR may be replaced with an N-type transistor.

In embodiments, the transistors T1, T2, T3, and T4, and ATR may include an amorphous silicon semiconductor, a monocrystalline silicon semiconductor, a polycrystalline silicon semiconductor, an oxide semiconductor, and the like.

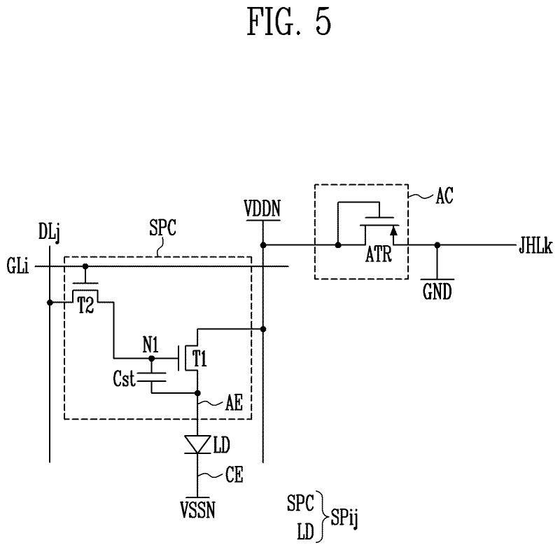

FIG. 5 is a drawing for explaining one or more other embodiments of a sub-pixel and an auxiliary circuit.

Referring to FIG. 5, the sub-pixel SPij may include a sub-pixel circuit SPC and a light-emitting element LD. The sub-pixel circuit SPC may include first and second transistors T1 and T2 and a storage capacitor Cst.

In the first transistor T1, a gate electrode may be connected to a first node N1, a first electrode may be connected to a first power voltage node VDDN, and a second electrode may be connected to an anode electrode AE of the light-emitting element LD. The first transistor T1 may be a driving transistor.

In the second transistor T2, a gate electrode may be connected to an i-th gate line GLi, a first electrode may be connected to a j-th data line DLj, and a second electrode may be connected to the first node N1. The second transistor T2 may be a switching transistor.

In the storage capacitor Cst, a first electrode may be connected to the first node N1, and a second electrode may be connected to the second electrode of the first transistor T1.

The light-emitting element LD may include the anode electrode AE, the cathode electrode CE, and the light-emitting layer. The light-emitting layer may be located between the anode electrode AE and the cathode electrode CE.

When a gate signal at a turn-on level (low level) is applied to the i-th gate line GLi, the second transistor T2 may be turned on. In this case, the data signal applied to the j-th data line DLj may be applied to the first node N1 through the second transistor T2. The storage capacitor Cst may maintain the voltage of the data signal. In response to the voltage of the data signal, the first transistor T1 may determine an amount of a driving current flowing from the first power voltage node VDDN to the second power voltage node VSSN. The light-emitting element LD may emit light with luminance corresponding to the amount of the driving current.

Because the configuration and function of the auxiliary circuit AC are the same as those in FIG. 4, redundant descriptions thereof will be omitted.

The first and second transistors T1 and T2 may be N-type transistors. Each of the first and second transistors T1 and T2 may be a MOSFET. However, embodiments are not limited thereto. For example, at least one of the first or second transistors T1 or T2 may be replaced with a P-type transistor.

In embodiments, the transistors T1 and T2 may include an amorphous silicon semiconductor, a monocrystalline silicon semiconductor, a polycrystalline silicon semiconductor, an oxide semiconductor, and the like.

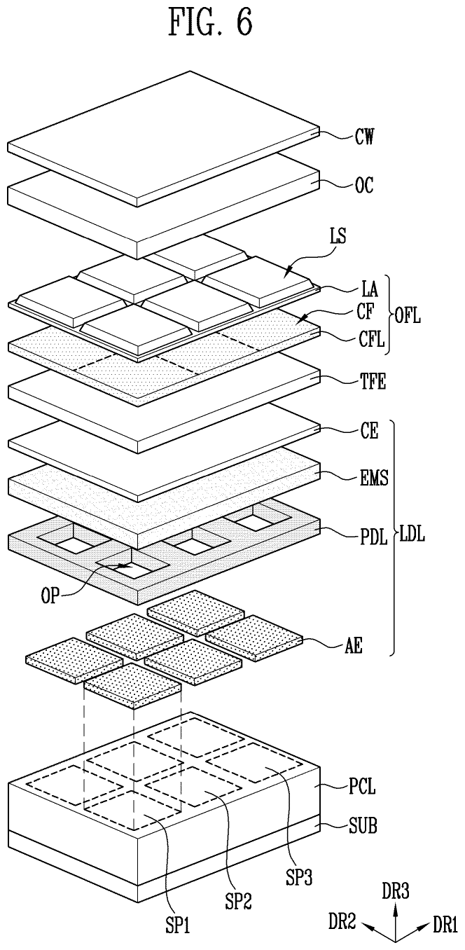

FIG. 6 illustrates an exploded perspective view of a portion of the display panel of FIG. 2.

The display panel DP may include a substrate SUB, a pixel circuit layer PCL, a light-emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon-on-insulator (SOI) layer, or a semiconductor-on-insulator (SeOI) layer. In other embodiments, the substrate SUB may include a glass substrate. In still other embodiments, the substrate SUB may include a polyimide (PI) substrate.

The pixel circuit layer PCL is located on the substrate SUB. The substrate SUB and/or the pixel circuit layer PCL may include insulating layers and conductive patterns located between the insulating layers. The conductive patterns of the pixel circuit layer PCL may function as at least some of circuit elements, wires, and the like. The conductive patterns may include copper, but embodiments are not limited thereto.

The circuit elements may include the sub-pixel circuit SPC (see FIG. 3) for each of first to third sub-pixels SP1, SP2, and SP3. The sub-pixel circuit SPC may include transistors and at least one capacitor. Each transistor may include a semiconductor portion including a source region, a drain region, and a channel region, and a gate electrode overlapping the semiconductor portion. In embodiments, when the substrate SUB is provided as a silicon substrate, the semiconductor portion may be included in the substrate SUB, and the gate electrode may be included in the pixel circuit layer PCL as the conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the sub-pixel, for example, a gate line, a light-emitting control line, and a data line. The wires may further include the wire connected to the first power voltage node VDDN of FIG. 3. In addition, the wires may further include the wire connected to the second power voltage node VSSN of FIG. 3.

The light-emitting element layer LDL may include anode electrodes AE, a pixel-defining layer PDL, a light-emitting structure EMS, and a cathode electrode CE.

The anode electrodes AE may be located on the pixel circuit layer PCL. The anode electrodes AE may contact circuit elements of the pixel circuit layer PCL. The anode electrodes AE may include an opaque conductive material capable of reflecting light, but embodiments are not limited thereto.

The pixel-defining layer PDL is located on the anode electrodes AE. The pixel-defining layer PDL may include (e.g., define) an opening OP exposing a portion of each of the anode electrodes AE. The opening OP of the pixel-defining layer PDL may be understood as light-emitting areas corresponding to the first to third sub-pixels SP1, SP2, and SP3, respectively.

In embodiments, the pixel-defining layer PDL may include an inorganic material. In this case, the pixel-defining layer PDL may include a plurality of stacked inorganic layers. For example, the pixel-defining layer PDL may include a silicon oxide (SiOx) and a silicon nitride (SiNx). In other embodiments, the pixel-defining layer PDL may include an organic material. However, the material of the pixel-defining layer PDL is not limited thereto.

The light-emitting structure EMS may be located on the anode electrodes AE exposed by the opening OP of the pixel-defining layer PDL. The light-emitting structure EMS may include a light-emitting layer configured to generate light, an electron transport layer configured to transport electrons, and a hole transport layer configured to transport holes.

In embodiments, the light-emitting structure EMS may fill the opening OP of the pixel-defining layer PDL, and may be located entirely on an upper portion of the pixel-defining layer PDL. In other words, the light-emitting structure EMS may extend across the first to third sub-pixels SP1, SP2, and SP3. In this case, at least some of the layers in the light-emitting structure EMS may be disconnected, bent, or removed at boundaries between the sub-pixels. However, embodiments are not limited thereto. For example, portions of the light-emitting structure EMS corresponding to the sub-pixels may be separated from each other, and each of them may be located within the opening OP of the pixel-defining layer PDL.

The cathode electrode CE may be located on the light-emitting structure EMS. The cathode electrode CE may extend across sub-pixels. As such, the cathode electrode CE may be provided as a common electrode for the sub-pixels.

The cathode electrode CE may be a thin metal layer with a thickness sufficient to transmit light emitted from the light-emitting structure EMS. The cathode electrode CE may be made of a metallic material or a transparent conductive material to have a relatively thin thickness. In embodiments, the cathode electrode CE may include at least one of various transparent conductive materials including an indium tin oxide, an indium zinc oxide, an indium tin zinc oxide, an aluminum zinc oxide, a gallium zinc oxide, a zinc tin oxide, or a gallium tin oxide. In other embodiments, the cathode electrode CE may include at least one of silver (Ag), magnesium (Mg), or a mixture thereof. However, the material of the cathode electrode CE is not limited thereto.

One of the anode electrodes AE, the portion of the light-emitting structure EMS overlapping it, and the portion of the cathode electrode CE overlapping it may be understood to configure one light-emitting element LD (see FIG. 3). In other words, each of the light-emitting elements of the sub-pixels may include one anode electrode, a portion of the light-emitting structure EMS overlapping it, and a portion of the cathode electrode CE overlapping it. In each of the first to third sub-pixels SP1, SP2, and SP3, holes injected from the anode electrode AE and electrons injected from the cathode electrode CE are transported into the light-emitting layer of the light-emitting structure EMS to form excitons, and when the excitons transition from the excited state to the ground state, light may be generated. The luminance of light may be determined depending on the amount of current flowing through the light-emitting layer. Depending on the configuration of the light-emitting layer, the wavelength range of the generated light may be determined.

The encapsulation layer TFE is located on the cathode electrode CE. The encapsulation layer TFE may cover the light-emitting element layer LDL and/or the pixel circuit layer PCL. The encapsulation layer TFE may be configured to reduce or prevent oxygen and/or moisture from penetrating into the light-emitting element layer LDL. In embodiments, the encapsulation layer TFE may include a structure in which one or more inorganic films and one or more organic films are alternately stacked. For example, the inorganic film may include a silicon nitride, a silicon oxide, or a silicon oxynitride (SiOxNy). For example, the organic film may include an organic insulating material, such as a polyacrylates resin, an epoxy resin, a phenolicresin, a polyamides resin, a polyimides rein, an unsaturated polyesters resin, a poly phenylenethers resin, a polyphenylenesulfides resin, or benzocyclobutene (BCB). However, the materials of the organic film and the inorganic film of the encapsulation layer TFE are not limited thereto.

The encapsulation layer TFE may further include a thin film containing an aluminum oxide (AlOx) to improve the encapsulation efficiency of the encapsulation layer TFE. The thin film containing an aluminum oxide may be located on the upper surface of the encapsulation layer TFE facing the optical functional layer OFL and/or the lower surface of the encapsulation layer TFE facing the light-emitting element layer LDL.

The thin film containing the aluminum oxide may be formed through an atomic layer deposition (ALD) method. However, embodiments are not limited thereto. The encapsulation layer TFE may further include a thin film made of at least one of various materials suitable for improving the encapsulation efficiency.

The optical functional layer OFL is located on the encapsulation layer TFE. The optical functional layer OFL may include a color filter layer CFL and a lens array LA.

The color filter layer CFL is located between the encapsulation layer TFE and the lens array LA. The color filter layer CFL is configured to selectively output light in a wavelength range or color corresponding to each sub-pixel by filtering light emitted from the light-emitting structure EMS. The color filter layer CFL includes color filters CF corresponding to the sub-pixels, and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light-emitting structure EMS of each sub-pixel.

The lens array LA is located on the color filter layer CFL. The lens array LA may include lenses LS respectively corresponding to the sub-pixels. Each of the lenses LS may improve light output efficiency by outputting light emitted from the light-emitting structure EMS in an intended path. The lens array LA may have a relatively high refractive index. For example, the lens array LA may have a higher refractive index than the overcoat layer OC. In embodiments, the lenses LS may include an organic material. In embodiments, the lenses LS may include an acrylate material. However, the material of the lenses LS is not limited thereto.

In embodiments, compared to the opening OP of the pixel-defining layer PDL, at least some of the color filters CF of the color filter layer CF and at least some of the lenses LS of the lens array LA may be shifted in a direction parallel to a plane defined by the first and second directions DR1 and DR2. For example, in the center area of the display area DA, the center of the color filter and the center of the lens may be aligned or overlapped with the center of the opening OP of the corresponding pixel-defining layer PDL when viewed in the third direction DR3. For example, in the central area of the display area DA, the opening OP of the pixel-defining layer PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding pixel-defining layer PDL when viewed in the third direction DR3. For example, in an area of the display area DA adjacent to the non-display area NDA, the opening OP of the pixel-defining layer PDL may partially overlap the corresponding color filter of the color filter layer CFL and the corresponding lens of the lens array LA. Accordingly, in the center of the display area DA, light emitted from the light-emitting structure EMS may be efficiently outputted in the normal direction of the display surface. Light emitted from the light-emitting structure EMS at the outside of the display area DA may be efficiently outputted in a direction inclined by an angle (e.g., predetermined angle) with respect to the normal direction of the display surface.

The overcoat layer OC may be located on the lens array LA. The overcoat layer OC may cover the optical functional layer OFL, the encapsulation layer TFE, the light-emitting structure EMS, and/or the pixel circuit layer PCL. The overcoat layer OC may include various materials suitable for protecting lower layers thereof from foreign substances, such as dust and moisture. For example, the overcoat layer OC may include at least one of an inorganic insulating film or an organic insulating film. For example, the overcoat layer OC may include an epoxy resin, but embodiments are not limited thereto. The overcoat layer OC may have a lower refractive index than the lens array LA.

The cover window CW may be located on the overcoat layer OC. The cover window CW is configured to protect lower layers thereof. The cover window CW may have a higher refractive index than the overcoat layer OC. The cover window CW may include glass, but embodiments are not limited thereto. For example, the cover window CW may be an encapsulation glass configured to protect components located thereunder. In other embodiments, the cover window CW may be omitted.

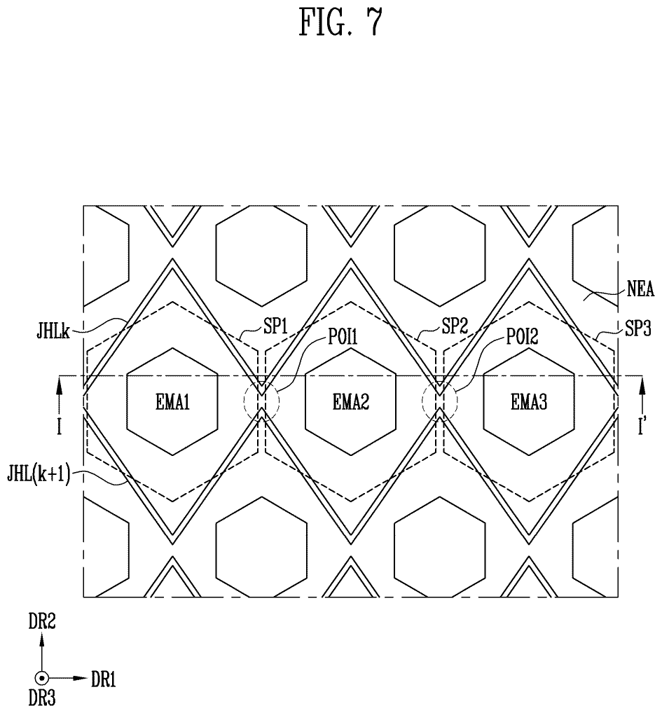

FIG. 7 illustrates a top plan view of a relationship between sub-pixels and metal lines.

Referring to FIG. 7, the first to third sub-pixels SP1, SP2, and SP3 arranged in first direction DR1 are illustrated as an example. The first sub-pixel SP1 may include a first light-emitting area EMA1 and a non-light-emitting area NEA around the first light-emitting area EMA1. The second sub-pixel SP2 may include a second light-emitting area EMA2 and a non-light-emitting area NEA around the second light-emitting area EMA2. The third sub-pixel SP3 may include a third light-emitting area EMA3 and a non-light-emitting area NEA around the third light-emitting area EMA3.

The first light-emitting area EMA1 may be an area in which light is emitted from a portion of the light-emitting structure EMS (see FIG. 6) corresponding to the first sub-pixel SP1. The second light-emitting area EMA2 may be an area in which light is emitted from a portion of the light-emitting structure EMS corresponding to the second sub-pixel SP2. The third light-emitting area EMA3 may be an area in which light is emitted from a portion of the light-emitting structure EMS corresponding to the third sub-pixel SP3. As described with reference to FIG. 6, each light-emitting area may be understood as the opening OP of the pixel-defining layer PDL corresponding to each of the first to third sub-pixels SP1, SP2, and SP3.

In FIG. 7, the light-emitting areas EMA1, EMA2, and EMA3 are illustrated as hexagonal shapes, but the light-emitting areas EMA1, EMA2, and EMA3 may be configured in other polygonal shapes including a quadrangular shape. Meanwhile, the light-emitting areas EMA1, EMA2, and EMA3 may be configured in a circular or oval shape. In addition, the shapes and areas of different light-emitting areas EMA1, EMA2, and EMA3 may be different.

The metal lines JHLk and JHL(k+1) extend in the first direction DR1 (e.g., in a zigzag manner), and may have a shape surrounding the corresponding light-emitting areas EMA1, EMA2, and EMA3. For example, the metal lines JHLk and JHL(k+1) may extend in the first direction DR1, and may extend in a zigzag shape.

However, because the metal lines JHLk and JHL(k+1) are not connected to each other on the display area DA, areas POI1 and POI2 that are not covered by the metal lines JHLk and JHL(k+1) may exist between the adjacent light-emitting areas EMA1, EMA2, and EMA3. However, two or more metal lines JHLk and JHL(k+1) may be located adjacent to each other with a minimum gap in the areas POI1 and POI2. An organic material existing in the areas POI1 and POI2 that do not overlap the metal lines JHLk and JHL(k+1) may be sublimated due to heat generated from two adjacent metal lines JHLk and JHL(k+1), and thus a leakage current through the organic material may be reduced or prevented.

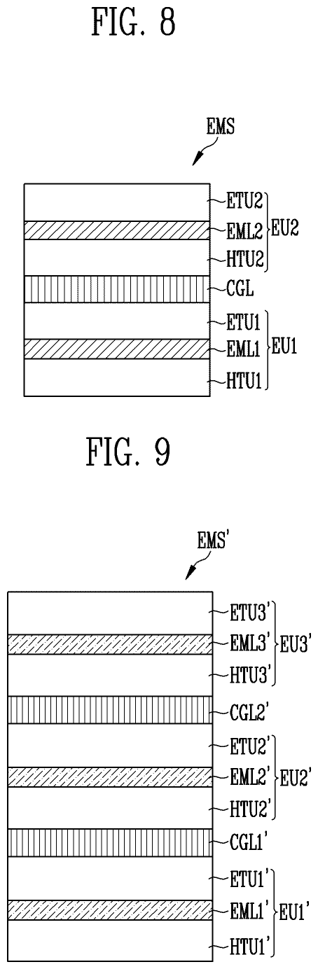

FIG. 8 illustrates a cross-sectional view of one or more embodiments of a light-emitting structure.

Referring to FIG. 8, the light-emitting structure EMS may have a tandem structure in which first and second light-emitting portions EU1 and EU2 are stacked.

Each of the first and second light-emitting portions EU1 and EU2 may include a light-emitting layer that generates light according to a current applied thereto. The first light-emitting portion EU1 may include a first light-emitting layer EML1, a first electron transport portion ETU1, and a first hole transport portion HTU1. The first light-emitting layer EML1 may be located between the first electron transport portion ETU1 and the first hole transport portion HTU1. The second light-emitting portion EU2 may include a second light-emitting layer EML2, a second electron transport portion ETU2, and a second hole transport portion HTU2. The second light-emitting layer EML2 may be located between the second electron transport portion ETU2 and the second hole transport portion HTU2.

Each of the first and second hole transport portions HTU1 and HTU2 may include at least one of a hole injection layer or a hole transport layer, and may further include a hole buffer layer, an electron-blocking layer, or the like as needed. The first and second hole transport portions HTU1 and HTU2 may have the same configuration or different configurations.

Each of the first and second electron transport portions ETU1 and ETU2 may include at least one of an electron injection layer or an electron transport layer, and may further include an electron buffer layer and a hole-blocking layer as needed. The first and second electron transport portions ETU1 and ETU2 may have the same configuration or different configurations.

A connection layer, which may be provided in the form of a charge generation layer CGL, may be located between the first light-emitting portion EU1 and the second light-emitting portion EU2 to connect them to each other. In embodiments, the charge generation layer CGL may have a stacked structure of a p dopant layer and an n dopant layer. For example, the p dopant layer may include a p-type dopant, such as HAT-CN, TCNQ, and/or NDP-9, and the n dopant layer may include an alkali metal, an alkaline earth metal, a lanthanide-based metal, or a combination thereof. However, embodiments are not limited thereto.

In embodiments, the first light-emitting layer EML1 and the second light-emitting layer EML2 may generate light of different colors. The light emitted from each of the first light-emitting layer EML1 and the second light-emitting layer EML2 may be mixed to be recognized as white light. For example, the first light-emitting layer EML1 may generate blue-colored light, and the second light-emitting layer EML2 may generate yellow-colored light. In embodiments, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In this case, an intermediate layer configured to perform a function of transporting holes and/or reducing or preventing transport of electrons may be further located between the first and second sub-light-emitting layers.

In other embodiments, the first light-emitting layer EML1 and the second light-emitting layer EML2 may generate light of the same color.

In embodiments, the light-emitting structure EMS may be formed through a vacuum deposition method, an inkjet printing method, or the like, but embodiments are not limited thereto.

FIG. 9 illustrates a cross-sectional view of one or more other embodiments of a light-emitting structure.

Referring to FIG. 9, a light-emitting structure EMS' may have a tandem structure in which first to third light-emitting portions EU1′ to EU3′ are stacked.

Each of the first to third light-emitting portions EU1′ to EU3′ may include a light-emitting layer that generates light according to a current applied thereto. The first light-emitting portion EU1′ may include a first light-emitting layer EML1′, a first electron transport portion ETU1′, and a first hole transport portion HTU1′. The first light-emitting layer EML1′ may be located between the first electron transport portion ETU1′ and the first hole transport portion HTU1′. The second light-emitting portion EU2′ may include a second light-emitting layer EML2′, a second electron transport portion ETU2′, and a second hole transport portion HTU2′. The second light-emitting layer EML2′ may be located between the second electron transport portion ETU2′ and the second hole transport portion HTU2′. The third light-emitting portion EU3′ may include a third light-emitting layer EML3′, a third electron transport portion ETU3′, and a third hole transport portion HTU3′. The third light-emitting layer EML3′ may be located between the third electron transport portion ETU3′ and the third hole transport portion HTU3′.

Each of the first to third hole transport portions HTU1′ to HTU3′ may include at least one of a hole injection layer or a hole transport layer, and may further include a hole buffer layer, an electron-blocking layer, or the like as needed. The first to third hole transport portions HTU1′ to HTU3′ may have the same configuration or different configurations.

Each of the first to third electron transport portions ETU1′ to ETU3′ may include at least one of an electron injection layer or an electron transport layer, and may further include an electron buffer layer and a hole-blocking layer as needed. The first to third electron transport portions ETU1′ to ETU3′ may have the same configuration or different configurations.

A first charge generation layer CGL1′ is located between the first light-emitting portion EU1′ and the second light-emitting portion EU2′. A second charge generation layer CGL2′ is located between the second light-emitting portion EU2′ and the third light-emitting portion EU3′.

In embodiments, the first to third light-emitting layers EML1′, EML2′, and EML3′ may generate light of different colors. Light emitted from each of the first to third light-emitting layers EML1′, EML2′, and EML3′ may be mixed to be viewed as white light. For example, the first light-emitting layer EML1′ may generate light of a blue color, the second light-emitting layer EML2′ may generate light of a green color, and the third light-emitting layer EML3′ may generate light of a red color.

In other embodiments, two or more of the first to third light-emitting layers EML1′, EML2′, and EML3′ may generate light of the same color.

Unlike illustrated in FIG. 8 and FIG. 9, each light-emitting structure EMS of each sub-pixel may include one light-emitting portion. In this case, light-emitting portions included in different sub-pixels SP1, SP2, and SP3 adjacent to each other may be configured to emit light of different colors. For example, the light-emitting portion of the first sub-pixel SP1 may emit red-colored light, the light-emitting portion of the second sub-pixel SP2 may emit green-colored light, and the light-emitting portion of the third sub-pixel SP3 may emit blue-colored light. In this case, the light-emitting portions of the first to third sub-pixels SP1, SP2, and SP3 are separated from each other, and each of them may be located in the opening OP of the pixel-defining layer PDL. In this case, at least some of the color filters CF1 to CF3 may be omitted.

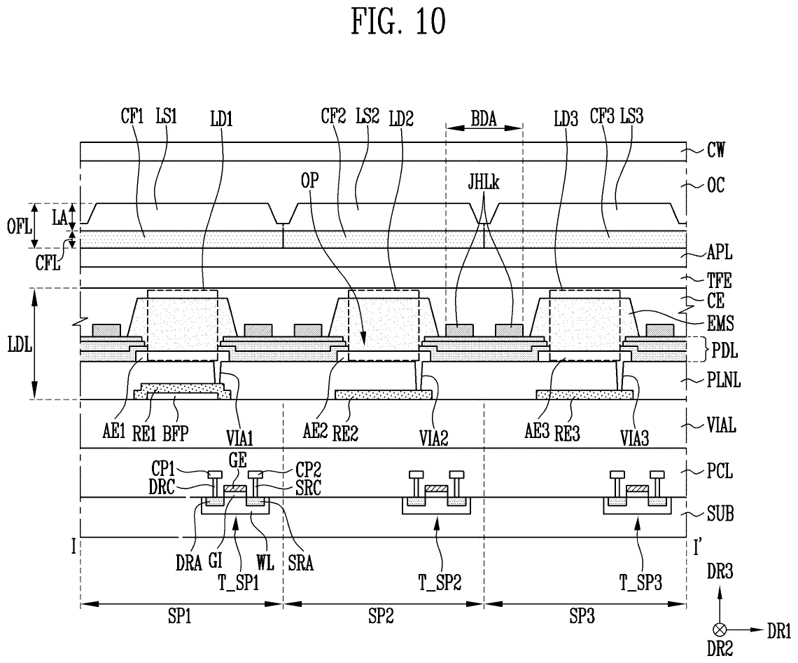

FIG. 10 illustrates a cross-sectional view taken along the line I-I′ of FIG. 7.

Referring to FIG. 10, the substrate SUB and the pixel circuit layer PCL located on the substrate SUB are provided.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements for each of the first to third sub-pixels SP1, SP2, and SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE.

The source area SRA and the drain area DRA may be located within the substrate SUB. A well WL formed through an ion injection process is located in the substrate SUB, and the source area SRA and the drain area DRA may be spaced apart from each other within the well WL. The area between the source area SRA and the drain area DRA within the well WL may be defined as a channel area.

The gate electrode GE overlaps the channel area between the source area SRA and the drain area DRA, and may be located on the pixel circuit layer PCL. The gate electrode GE may be separated from the well WL or the channel area by an insulating material, such as a gate-insulating layer GI. The gate electrode GE may include a conductive material.

Layers included in the pixel circuit layer PCL include insulating layers, and conductive patterns located between the insulating layers. The conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1. In addition, the auxiliary transistor ATR of the auxiliary circuit AC may be configured similarly to the transistor T_SP1 of the first sub-pixel SP1.

As such, the substrate SUB and the pixel circuit layer PCL may include circuit elements of each of the first to third sub-pixels SP1, SP2, and SP3 and the auxiliary transistors ATR of the auxiliary circuit AC. Meanwhile, in one or more other embodiments, the auxiliary transistor ATR may be positioned at an another layer in the third direction DR3 based on the transistors T_SP1, T_SP2, and T_SP3 of each of the first to third sub-pixels SP1, SP2, and SP3.

A via layer VIAL is located on the pixel circuit layer PCL. The via layer VIAL covers the pixel circuit layer PCL, and may have an overall flat surface. The via layer VIAL is configured to flatten steps on the pixel circuit layer PCL. The via layer VIAL may include at least one of a silicon oxide (SiOx), a silicon nitride (SiNx), or a silicon carbon nitride (SiCN), but embodiments are not limited thereto.

The light-emitting element layer LDL is located on the via layer VIAL. The light-emitting element layer LDL may include first to third reflective electrodes RE1, RE2, and RE3, a planarization layer PLNL, first to third anode electrodes AE1, AE2, and AE3, a pixel-defining layer PDL, a light-emitting structure EMS, and a cathode electrode CE.

The first to third reflective electrodes RE1, RE2, and RE3 are located in the first to third sub-pixels SP1, SP2, and SP3 on the via layer VIAL, respectively. Each of the first to third reflective electrodes RE1, RE2, and RE3 may contact a circuit element located on the pixel circuit layer PCL through a via penetrating the via layer VIAL.

The first to third reflective electrodes RE1, RE2, and RE3 may function as full mirrors that reflect light emitted from the light-emitting structure EMS toward the display surface (or the cover window CW). The first to third reflective electrodes RE1, RE2, and RE3 may include metallic materials suitable for reflecting light. The first to third reflective electrodes RE1, RE2, and RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected therefrom, but embodiments are not limited thereto.

In embodiments, a connection electrode may be located below each of the first to third reflective electrodes RE1, RE2, and RE3. The connection electrode may improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and/or the like, but embodiments are not limited thereto. In embodiments, a corresponding reflective electrode may be located between the multiple layers of the connecting electrode.

A buffer pattern BFP may be located below at least one of the first to third reflective electrodes RE1, RE2, or RE3. The buffer pattern BFP may include an inorganic material, such as a silicon carbon nitride, but embodiments are not limited thereto. Due to the arrangement of the buffer pattern BFP, the height of the corresponding reflective electrode in the third direction DR3 may be adjusted. For example, the buffer pattern BFP may be located between the first reflective electrode RE1 and the via layer VIAL to adjust the height of the first reflective electrode RE1.

The first to third reflective electrodes RE1, RE2, and RE3 may function as full mirrors, and the cathode electrode CE may function as a half mirror. Light emitted from the light-emitting layer of the light-emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light-emitting layer of the corresponding light-emitting structure EMS.

The first sub-pixel SP1 may have a shorter resonance distance than other sub-pixels due to the presence of the buffer pattern BFP. The resonance distance adjusted in this way may allow light in a corresponding wavelength range (for example, red color) to be effectively and efficiently amplified. Accordingly, the first sub-pixel SP1 may effectively and efficiently output light in the corresponding wavelength range.

In FIG. 10, the buffer pattern BFP is shown to be provided in the first sub-pixel SP1 and not in the second and third sub-pixels SP2 and SP3, but the embodiments are not limited thereto. The buffer pattern may be also provided in at least one of the second or third sub-pixels SP2 or SP3, so that the resonance distance of at least one of the second or third sub-pixels SP2 or SP3 may be adjusted. For example, the first to third sub-pixels SP1, SP2, and SP3 may correspond to red, green, and blue, respectively, the distance between the first reflective electrode RE1 and the cathode electrode CE may be less than the distance between the second reflective electrode RE2 and the cathode electrode CE. Also, the distance between the second reflective electrode RE2 and the cathode electrode CE may be less than the distance between the third reflective electrode RE3 and the cathode electrode CE.

To planarize the steps between the first to third reflective electrodes RE1, RE2, and RE3, the planarization layer PLNL may be located on the via layer VIAL and the first to third reflective electrodes RE1, RE2, and RE3. The planarization layer PLNL may entirely cover the first to third reflective electrodes RE1, RE2, and RE3 and the via layer VIAL, and may have a flat surface. In embodiments, the planarization layer PLNL may be omitted.

The first to third anode electrodes AE1, AE2, and AE3 respectively overlapping the first to third reflective electrodes RE1, RE2, and RE3 are located on the planarization layer PLNL. The first to third anode electrodes AE1, AE2, and AE3 may have shapes similar to the first to third light-emitting areas EMA1, EMA2, and EMA3 of FIG. 7 when viewed in the third direction DR3. The first to third anode electrodes AE1, AE2, and AE3 are respectively connected to the first to third reflective electrodes RE1, RE2, and RE3. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

In embodiments, the first to third anode electrodes AE1, AE2, and AE3 may include at least one of transparent conductive materials, such as an indium tin oxide (ITO), an indium zinc oxide (IZO), a zinc oxide (ZnOx), an indium gallium zinc oxide (IGZO), or an indium tin zinc oxide (ITZO). However, the materials of the first to third anode electrodes AE1, AE2, and AE3 are not limited thereto. For example, the first to third anode electrodes AE1, AE2, and AE3 may include a titanium nitride.

In embodiments, insulating layers for adjusting a height of one or more of the first to third anode electrodes AE1, AE2, and AE3 may be further provided. The insulating layers may be located between at least one of the first to third anode electrodes AE1, AE2, and/or AE3 and/or the corresponding reflective electrode. In this case, the planarization layer PLNL and/or the buffer pattern BFP may be omitted. For example, the first to third sub-pixels SP1, SP2, and SP3 may respectively correspond to red, green, and blue, the distance between the first anode electrode AE1 and the cathode electrode CE may be less than the distance between the second anode electrode AE2 and the cathode electrode CE. Also, the distance between the second anode electrode AE2 and the cathode electrode CE may be less than the distance between the third anode electrode AE3 and the cathode electrode CE. The pixel-defining layer PDL is located on some of the first to third anode electrodes AE1, AE2, and AE3 and the planarization layer PLNL. The pixel-defining layer PDL may include an opening OP exposing a portion of each of the first to third anode electrodes AE1, AE2, and AE3. The opening OP of the pixel-defining layer PDL may define the light-emitting area for each of the first to third sub-pixels SP1, SP2, and SP3. As such, the pixel-defining layer PDL may be located in the non-light-emitting area NEA of FIG. 7 to define the first to third light-emitting areas EMA1, EMA2, and EMA3 of FIG. 7.

In embodiments, the pixel-defining layer PDL may include a plurality of inorganic insulating layers. Each of the plurality of inorganic insulating layers may include at least one of a silicon oxide (SiOx) or a silicon nitride (SiNx). For example, the pixel-defining layer PDL may include first to third inorganic insulating layers sequentially stacked, and each of the first to third inorganic insulating layers may include a silicon nitride, a silicon oxide, and a silicon nitride. However, embodiments are not limited thereto. The first to third inorganic insulating layers may have a step-shaped cross-section in an area adjacent to the opening OP.

The metal line JHLk may be provided in the boundary area BDA between neighboring sub-pixels. Each of the metal lines (JHL1, JHL2, JHL3, . . . , JHLo) including the metal line JHLk may be located on the pixel-defining layer PDL (see FIG. 2).

Each of the metal lines JHL1 to JHLo including the metal line JHLk may contact the cathode electrode CE of the light-emitting elements of the sub-pixels SP in the display area DA. For example, the metal lines JHL1 to JHLo may sublimate a portion of the light-emitting structure EMS located nearby by dissipating heat by Joule heating after the light-emitting structure EMS is stacked. In the case of the light-emitting structure EMS of FIG. 8, the light-emitting structure EMS may not remain on the metal line JHLk because a Joule heating process occurs after the first light-emitting portion EU1, the charge generation layer CGL, and the second light-emitting portion EU2 are all stacked. In the case of the light-emitting structure EMS of FIG. 9, the light-emitting structure EMS' may not remain on the metal line JHLk because a Joule heating process is performed after the first light-emitting portion EU1′, the first charge generation layer CGL1′, the second light-emitting portion EU2′, the second charge generation layer CGL2′, and the third light-emitting portion EU3′ are all stacked. Accordingly, a leakage current through portions of the light-emitting structure EMS cut off by the metal lines JHL1 to JHLo may be reduced or prevented. The metal lines JHL1 to JHLo may be exposed to the outside of the light-emitting structure EMS, and may contact the cathode electrode CE that is subsequently deposited. In this case, as illustrated in FIG. 2, the reference voltage GND may be the same as the second power voltage VSS.

The light-emitting structure EMS may be located on the anode electrodes AE exposed by the opening OP of the pixel-defining layer PDL. In embodiments, the light-emitting structure EMS may be formed through a process, such as vacuum deposition, inkjet printing, or the like. The light-emitting structure EMS may fill the opening OP of the pixel-defining layer PDL, and may be located entirely across the first to third sub-pixels SP1, SP2, and SP3. As previously described, the light-emitting structure EMS may be at least partially cut off in the boundary area BDA by the metal line JHLk. Accordingly, when the display panel DP operates, the current leaking from each of the first to third sub-pixels SP1, SP2, and SP3 to the neighboring sub-pixel through the layers included in the light-emitting structure EMS may decrease. Accordingly, the first to third light-emitting elements LD1 to LD3 may operate with relatively high reliability.

The cathode electrode CE may be located on the light-emitting structure EMS. The cathode electrode CE may be provided commonly for the first to third sub-pixels SP1, SP2, and SP3. The cathode electrode CE may function as a half mirror that partially transmits, and partially reflects, light emitted from the light-emitting structure EMS.

The first anode electrode AE1, the portion of the light-emitting structure EMS overlapping the first anode electrode AE1, and the portion of the cathode electrode CE overlapping the first anode electrode AE1 may configure the first light-emitting element LD1. The second anode electrode AE2, the portion of the light-emitting structure EMS overlapping the second anode electrode AE2, and the portion of the cathode electrode CE overlapping the second anode electrode AE2 may configure the second light-emitting element LD2. The third anode electrode AE3, the portion of the light-emitting structure EMS overlapping the third anode electrode AE3, and the portion of the cathode electrode CE overlapping the third anode electrode AE3 may configure the third light-emitting element LD3.

The encapsulation layer TFE is located on the cathode electrode CE. The encapsulation layer TFE may reduce or prevent oxygen and/or moisture from penetrating into the light-emitting element layer LDL.

The optical functional layer OFL is located on the encapsulation layer TFE. In embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1, SP2, and SP3. The first to third color filters CF1 to CF3 may pass light in different wavelength ranges. For example, the first to third color filters CF1 to CF3 may pass red, green, and blue colored light, respectively.

In embodiments, the first to third color filters CF1 to CF3 may partially overlap in the boundary area BDA. In other embodiments, the first to third color filters CF1 to CF3 may be spaced apart from each other, and a black matrix may be provided between the first to third color filters CF1 to CF3.

The lens array LA is located on the color filter layer CFL. The lens array LA may include first to third lenses LS1, LS2, and LS3 respectively corresponding to the first to third sub-pixels SP1, SP2, and SP3. The first to third lenses LS1, LS2, and LS3 may improve light output efficiency by outputting the light emitted from the first to third light-emitting elements LD1 to LD3, respectively, along an intended path.

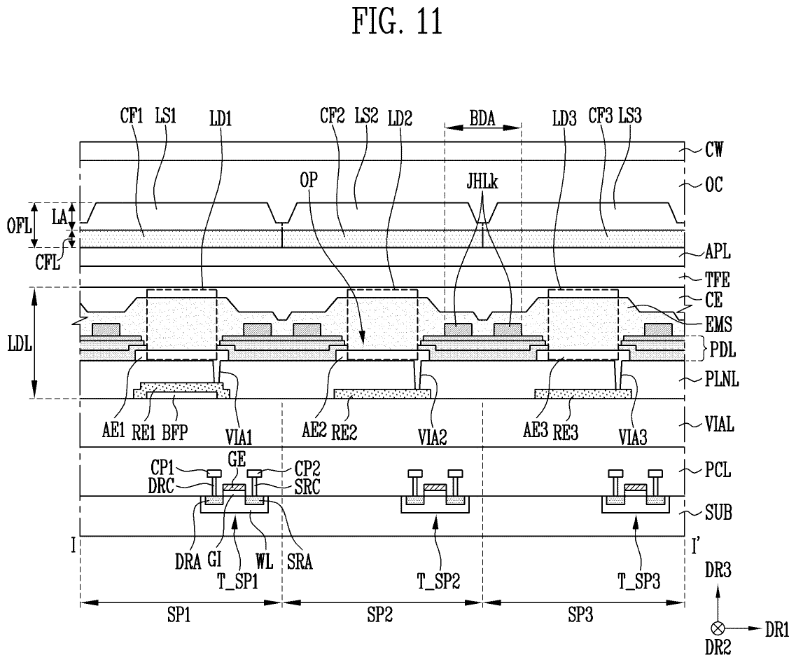

FIG. 11 illustrates a cross-sectional view of one or more other embodiments of FIG. 10.

The light-emitting structure EMS of FIG. 11 is different from the light-emitting structure EMS of FIG. 10 in that a portion of the light-emitting structure EMS remains on the metal line JHLk. That is, each of the metal lines JHL1 to JHLo including the metal line JHLk may not contact the cathode electrode CE of the light-emitting elements of the sub-pixels SP in the display area DA (see FIG. 2).

For example, after the first light-emitting portion EU1 and the charge generation layer CGL are stacked on the metal line JHLk, heat by Joule heating is dissipated in the metal line JHLk, thereby sublimating a portion of the first light-emitting portion EU1 and the charge generation layer CGL located nearby. Thereafter, stacking of the second light-emitting portion EU2 may proceed (see FIG. 8). In this case, the metal line JHLk may contact the remaining second light-emitting portion EU2.

For another example, after the first light-emitting portion EU1′, the first charge generation layer CGL1′, the second light-emitting portion EU2′, and the second charge generation layer CGL2′ are stacked on the metal line JHLk, portions of the first light-emitting portion EU1′, the first charge generation layer CGL1′, the second light-emitting portion EU2′, and the second charge generation layer CGL2′ may be sublimated by dissipating heat by Joule heating in the metal line JHLk. Thereafter, stacking of the third light-emitting portion EU3′ may proceed (see FIG. 9). In this case, the metal line JHLk may contact the remaining third light-emitting portion EU3′.

Because the highly conductive charge generation layer CGL, first charge generation layer CGL1′, or second charge generation layer CGL2′ may be sublimated, a leakage current may be reduced or prevented even if a portion of the light-emitting structure EMS remains.

FIG. 12A to FIG. 12F are drawings for explaining other embodiments of the display panel of FIG. 2.

Referring to FIG. 12A, the number of the auxiliary circuits AC of the display panel DPa may be less than the number of the sub-pixels SP.

The number of suitable auxiliary circuits AC may vary depending on the design of the display panel DPa. For example, as a result of measuring the voltage drop of the metal lines JHL1 to JHLo of the display panel DPa, the number of the auxiliary circuits AC may be reduced as the voltage drop is not large.

Referring to FIG. 12B, the number of the auxiliary circuits AC of the display panel DPb may be less than the number of the sub-pixels SP. In this case, in the display area DA, the density of the auxiliary circuits AC may increase in the first direction DR1, which is the extension direction of the metal lines JHL1 to JHLo.

A voltage drop may occur more at portions of the metal lines JHL1 to JHLo close to the second metal pad JPD2 than at portions of the metal lines JHL1 to JHLo close to the first metal pad JPD1 to which the power voltage is applied. Therefore, the voltages of respective portions of the metal lines JHL1 to JHLo may be made uniform by concentrating and locating the auxiliary circuits AC near the second metal pad JPD2.

Referring to the display panel DPc of FIG. 12C, and the display panel DPd of FIG. 12D, at least one of the auxiliary circuits AC may be connected to two or more points of the same metal line. In FIG. 12C, when the auxiliary current supplied from the auxiliary circuits AC is sufficient, the number of the auxiliary circuits AC may be reduced. In FIG. 12D, the voltage drop may be more uniformly compensated, and the auxiliary current may be stably supplied from the adjacent auxiliary circuit AC even when any auxiliary circuit AC fails.

Referring to the display panel DPe of FIG. 12E, the auxiliary circuits AC may include a first auxiliary circuit AC1 and a second auxiliary circuit AC2 connected to the same metal line JHL1. The length of the first connection line CNL1 connecting the first auxiliary circuit AC1 and the metal line JHL1 may be longer than the length of the second connection line CNL2 connecting the second auxiliary circuit AC2 and the metal line JHL1.

In this case, the second auxiliary circuit AC2 may be located in the first direction DR1 from the first auxiliary circuit AC1. Portions of the metal lines JHL1 to JHLo close to the first metal pad JPD1 to which the power voltage is applied may have a smaller voltage drop than portions of the metal lines JHL1 to JHLo close to the second metal pad JPD2. By configuring the first connection line CNL1 to be relatively long near the first metal pad JPD1 in which a voltage drop occurs relatively small, power received by the metal line JHL1 from the first auxiliary circuit AC1 may be reduced. Accordingly, a voltage drop amount of a portion of the metal line JHL1 connected to the first connection line CNL1 of the first auxiliary circuit AC1 may be the same as a voltage drop amount of a portion of the metal line JHL1 connected to the second connection line CNL2 of the second auxiliary circuit AC2.

Referring to the display panel DPf of FIG. 12F, at least one of the auxiliary circuits AC may be connected to two or more different metal lines. For example, the auxiliary circuit AC may be connected to two adjacent metal lines JHL1 and JHL2 in the second direction DR2. When the auxiliary current supplied from the auxiliary circuits AC is sufficient, the number of the auxiliary circuits AC may be reduced.

The embodiments of the present disclosure are not limited by the embodiments of FIG. 2 and FIG. 12A to FIG. 12F. The embodiments of FIG. 2 and FIG. 12A to FIG. 12F may be combined with each other.

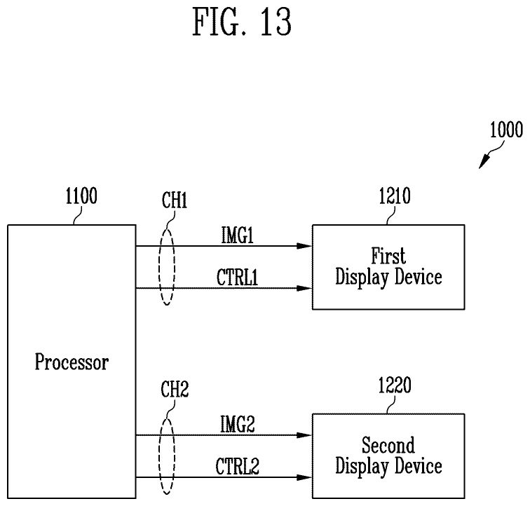

FIG. 13 illustrates a block diagram of one or more embodiments of a display system.

Referring to FIG. 13, the display system 1000 may include a processor 1100 and one or more display devices 1210 and 1220.

The processor 1100 can perform various tasks and calculations. In embodiments, the processor 1100 may include an application processor, a graphics processor, a microprocessor, a central processing unit (CPU), and the like. The processor 1100 may be connected to and control other constituent elements of the display system 1000 through a bus system.

In FIG. 13, the display system 1000 is shown to include the first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing image display functions, such as a portable computer, a mobile phone, a smart phone, a tablet personal computer (PC), a smart watch, a watch phone, a portable multimedia player (PMP), a navigation system, and an ultra-mobile personal computer (UMPC). In addition, the display system 1000 may include at least one of a head-mounted display device (HMD), a virtual reality (VR) device, a mixed reality (MR) device, or an augmented reality (AR) device.

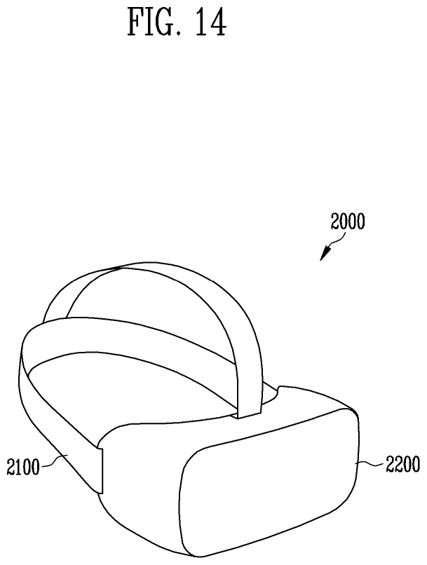

FIG. 14 illustrates a perspective view of an example of application of the display system of FIG. 13.

Referring to FIG. 14, the display system 1000 of FIG. 13 may be applied to a head-mounted display device 2000. The head-mounted display device 2000 may be a wearable electronic device that may be worn on the user's head.

The head-mounted display device 2000 may include a head-mounted band 2100 and a display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may be configured to surround the side portion of the user's head, and the vertical band may be configured to surround the upper portion of the user's head. However, embodiments are not limited thereto. For example, the head-mounted band 2100 may be implemented in the form of a spectacle frame, a helmet, or the like.

The display device accommodation case 2200 may accommodate the first and second display devices 1210 and 1220 of FIG. 13. The display device accommodation case 2200 may further accommodate the processor 1100 of FIG. 13.

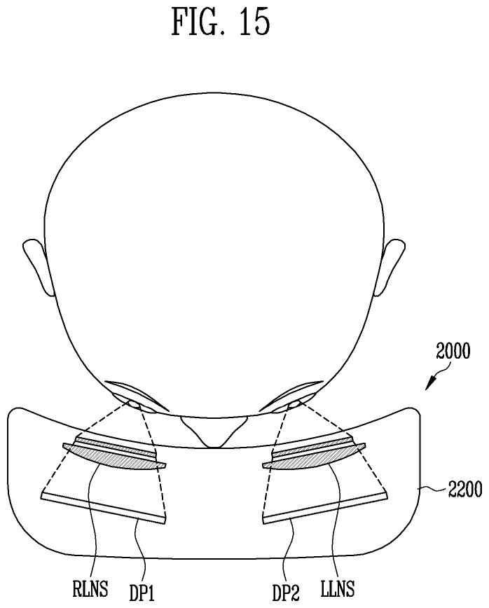

FIG. 15 illustrates a head-mounted display device worn on a user of FIG. 14.

Referring to FIG. 15, a first display panel DP1 of the first display device 1210 and a second display panel DP2 of the second display device 1220 are located in the head-mounted display device 2000. The head-mounted display device 2000 may further include one or more lenses LLNS and RLNS.

In the display device accommodation case 2200, the right eye lens RLNS may be located between the first display panel DP1 and the right eye of the user. In the display device accommodation case 2200, the left eye lens LLNS may be located between the second display panel DP2 and the left eye of the user.

An image outputted from the first display panel DP1 may be shown to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image outputted from the second display panel DP2 may be shown to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

In embodiments, each of the right eye lens RLNS and the left eye lens LLNS may include an optical lens having a cross-section of a pancake shape. In embodiments, each of the right eye lens RLNS and the left eye lens LLNS may include a multi-channel lens including sub-areas with different optical characteristics. In this case, each display panel outputs images corresponding to the sub-areas of the multi-channel lens, and the output images may pass through the sub-areas and be viewed by the user.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims. Therefore, those skilled in the art will understand that various modifications and other equivalent embodiments of the present disclosure are possible. Consequently, the true technical protective scope of the present disclosure must be determined based on the technical spirit of the appended claims, with functional equivalents thereof to be included therein.

What is claimed is:

1. A display device comprising:
a substrate having a display area and a non-display area;
sub-pixels in the display area;
a metal line crossing the non-display area and the display area, and extending in the display area to be spaced apart from light-emitting areas of the sub-pixels in a plan view; and
an auxiliary circuit connected to the metal line in the display area.

2. The display device of claim 1, wherein the sub-pixels and the auxiliary circuit are coupled to a first power voltage node.

3. The display device of claim 2, wherein the auxiliary circuit comprises an auxiliary transistor coupled between the metal line and the first power voltage node.

4. The display device of claim 3, wherein a first electrode and a gate electrode of the auxiliary transistor are coupled to the first power voltage node.

5. The display device of claim 4, wherein a second electrode of the auxiliary transistor is coupled to the metal line, and is configured to receive a reference voltage.

6. The display device of claim 2, wherein the sub-pixels comprise:
a light-emitting element;
a first transistor having a gate electrode coupled to a first node, a first electrode coupled to a second node, and a second electrode coupled to an anode of the light-emitting element;
a second transistor having a gate electrode coupled to a gate line, a first electrode coupled to a data line, and a second electrode coupled to the first node; and
a storage capacitor having a first electrode coupled to the first power voltage node, and a second electrode coupled to the first node.

7. The display device of claim 6, wherein the sub-pixels further comprise:
a third transistor having a gate electrode coupled to the second node, a first electrode coupled to the first power voltage node, and a second electrode coupled to the second node; and
a fourth transistor having a gate electrode and a first electrode coupled to the anode of the light-emitting element, and a second electrode configured to receive a reference voltage.

8. A display device comprising:
a substrate containing a display area and a non-display area;
sub-pixels in the display area;
metal lines crossing the non-display area and the display area, and extending in the display area to be spaced apart from light-emitting areas of the sub-pixels in a plan view; and
auxiliary circuits coupled to at least one of the metal lines in the display area.

9. The display device of claim 8, wherein a number of the auxiliary circuits is less than a number of the sub-pixels.

10. The display device of claim 9, wherein the metal lines extend in a first direction, and
wherein, in the display area, a density of the auxiliary circuits increases toward the first direction.

11. The display device of claim 1, wherein at least one of the auxiliary circuits is coupled to two or more points of a same metal line.

12. The display device of claim 8, wherein at least one of the auxiliary circuits is coupled to two or more different metal lines.

13. The display device of claim 8, wherein the auxiliary circuits comprise a first auxiliary circuit and a second auxiliary circuit coupled to a same metal line, and
wherein a length of a first connection line coupling the first auxiliary circuit and one of the metal lines is longer than a length of a second connection line coupling the second auxiliary circuit and the one of the metal lines.

14. The display device of claim 8, further comprising:
a first metal pad in the non-display area, and coupled to first ends of the metal lines; and
a second metal pad in the non-display area, and coupled to second ends of the metal lines,
wherein the display area is between the first metal pad and the second metal pad.

15. The display device of claim 8, wherein the metal lines are on a pixel-defining layer defining the light-emitting areas of the sub-pixels in the display area.

16. The display device of claim 15, wherein the metal lines respectively contact cathodes of light-emitting elements of the sub-pixels.

17. The display device of claim 15, wherein light-emitting elements of the sub-pixels comprise a first light-emitting portion, and a second light-emitting portion stacked on the first light-emitting portion, and contacting a corresponding one of the metal lines.

18. A wearable device comprising:
a first display panel; and
a second display panel,
wherein the first display panel and the second display panel comprise:
a substrate comprising a display area and a non-display area;
sub-pixels in the display area;
metal lines crossing the non-display area and the display area, and extending in the display area to be spaced apart from light-emitting areas of the sub-pixels in a plan view; and
auxiliary circuits coupled to at least one of the metal lines in the display area.

19. The wearable device of claim 18, wherein the sub-pixels and the auxiliary circuits are coupled to a first power voltage node.

20. The wearable device of claim 19, wherein the auxiliary circuits comprise an auxiliary transistor coupled between one of the metal lines and the first power voltage node,
wherein a first electrode and a gate electrode of the auxiliary transistor are coupled to the first power voltage node, and
wherein a second electrode of the auxiliary transistor is coupled to the one of the metal lines.
